(19) United States
(12) Patent Application Publication
(10) Pub. No.: US 2026/0286527 A1
(43) Pub. Date: Sep. 24, 2026

(54) Substrate Support and Substrate Processing Apparatus

(71) Applicant: Tokyo Electron Limited, Tokyo (JP)

(72) Inventors: Yuki MOTOMURA, Yamanashi (JP); Shinji ORIMOTO, Fremont, CA (US); Hiroshi SONE, Tokyo (JP)

(21) Appl. No.: 19/558,206

(22) Filed: Mar. 5, 2026

(30) Foreign Application Priority Data
Mar. 18, 2025 (JP) 2025-043797

(51) Int. Cl. C23C 16/458

(52) U.S. Cl. CPC C23C 16/4586

(57) ABSTRACT

Provided is a substrate support comprising: a substrate mounting part having a mounting surface for mounting a substrate, a back surface provided on the opposite side of the mounting surface, and a recess formed in the back surface; a rod-shaped temperature measuring part configured to detect a temperature at a tip end thereof, the tip end being inserted into and brought into contact with the recess to detect a temperature; and a heat transfer part including a plate-shaped flange portion having a through-hole through which the temperature measuring part penetrates and in thermal contact with the back surface, and a cylindrical portion protruding from the flange portion and whose inner surface is brought into contact with the temperature measuring part.

### CROSS-REFERENCE TO RELATED APPLICATIONS

This application claims priority to Japanese Patent Application No. 2025-043797 filed on March 18, 2025, the entire contents of which are incorporated herein by reference.

### Technical Field

The present disclosure relates to a substrate support and a substrate processing apparatus.

### Background

Japanese Patent No. 7278139 discloses a substrate support having a substrate mounting surface on which a substrate is placed in a processing apparatus for processing a substrate. Japanese Patent No. 7278139 discloses that the substrate support includes a support body and a thermocouple that detects the temperature near the substrate mounting surface of the support body, wherein the detected temperature is used to control the temperature of the substrate mounting surface.

Japanese Laid-open Patent Publication No. 2010-109346 discloses a mounting table structure that is installed in an evacuable processing chamber and places a target object thereon. Japanese Laid-open Patent Publication No. 2010-109346 discloses that the mounting table structure includes a functional rod that is designed to be inserted into a protective support line so that an upper end thereof reaches the table, and that the functional rod is a thermocouple for measuring the temperature of the mounting table.

### SUMMARY

The present disclosure provides a technology for improving responsiveness in measuring a temperature of a substrate support.

In accordance with an aspect of the subject application, there is provided a substrate support comprising: a substrate mounting part having a mounting surface for mounting a substrate, a back surface provided on the opposite side of the mounting surface, and a recess formed in the back surface; a rod-shaped temperature measuring part configured to detect a temperature at a tip end thereof, the tip end being inserted into and brought into contact with the recess to detect a temperature; and a heat transfer part including a plate-shaped flange portion having a through-hole through which the temperature measuring part penetrates and in thermal contact with the back surface, and a cylindrical portion protruding from the flange portion and whose inner surface is brought into contact with the temperature measuring part.

### BRIEF DESCRIPTION OF THE DRAWINGS

FIG. 1 illustrates a schematic configuration of a substrate processing apparatus including a substrate support according to an embodiment.

FIG. 2 illustrates in detail an attachment portion of a temperature sensor at the substrate support according to the embodiment.

FIG. 3 illustrates heat flow near the attachment portion of the temperature sensor at the substrate support according to the embodiment.

FIG. 4 illustrates heat flow near an attachment portion of a temperature sensor at a substrate support of a reference example.

### DETAILED DESCRIPTION

Hereinafter, embodiments will be described with reference to the accompanying drawings. The present disclosure is not limited to these examples, but is defined by the scope of the claims, and is intended to include all modifications within the meaning and scope equivalent to the scope of the claims.

In the description and drawings according to the respective embodiments, components having substantially the same or corresponding functional configurations may be denoted by the same or corresponding reference numerals, and redundant descriptions thereof may be omitted. Further, for ease of understanding, the scales of individual components in the drawings may be different from the actual scales.

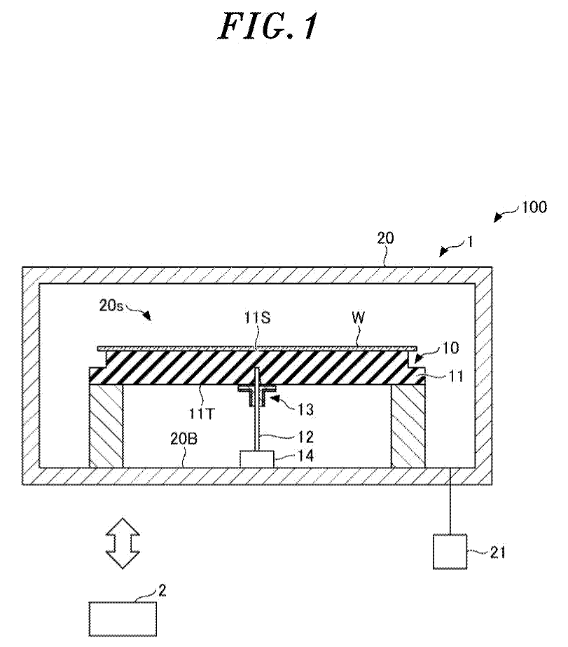

A substrate processing apparatus including a substrate support according to an embodiment will be described. FIG. 1 illustrates a schematic configuration of a substrate processing apparatus 100 including a substrate support 10, which is an example of a substrate support according to the embodiment.

The substrate processing apparatus 100 performs desired processing on a substrate W in a low-pressure state, such as a vacuum state. The substrate processing apparatus 100 is, e.g., an etching apparatus or a film forming apparatus.

The substrate processing apparatus 100 includes a substrate processing part 1 and a controller 2. The controller 2 controls the substrate processing part 1.

The substrate processing part 1 includes the substrate support 10 and a processing chamber 20.

The processing chamber 20 has therein a processing space 20s. The processing chamber 20 isolates the processing space 20s from an external atmospheric pressure space so that the processing space 20s is maintained at a low-pressure state, such as a vacuum state.

The processing chamber 20 includes an exhaust part 21. The exhaust part 21 exhausts a gas in the processing space 20s. The exhaust part 21 includes, e.g., a pressure control valve and a vacuum pump. The pressure control valve controls a pressure in the processing space 20s. The vacuum pump includes, e.g., a turbomolecular pump, a dry pump, or a combination of a turbomolecular pump and a dry pump.

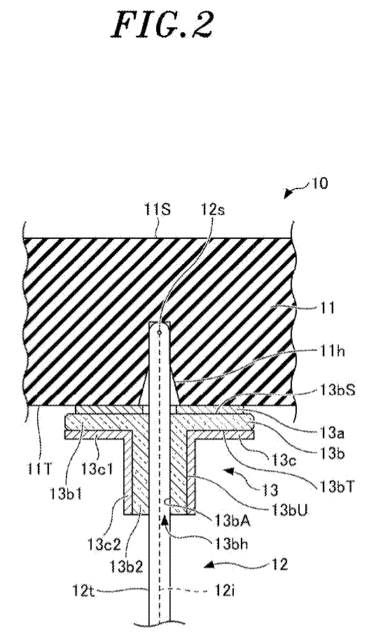

The substrate support 10 includes a substrate mounting part 11, a temperature measuring part 12, a heat transfer promoting part 13, and a support part 14. The components of the substrate support 10 and the arrangement thereof will be described in detail below. FIG. 2 illustrates in detail an attachment portion of the temperature measuring part 12 at the substrate mounting part 11, which is an example of the substrate support according to the embodiment.

The substrate mounting part 11 places a substrate W thereon. The substrate mounting part 11 may include a heating part for heating the substrate W, such as a heater, or a cooling part for cooling the substrate W, such as a channel through which a cooling medium flows. The substrate mounting part 11 may also include a temperature control part for controlling the temperature of the substrate W by heating or cooling the substrate W, such as a channel through which a temperature control medium flows. Further, the substrate mounting part 11 may include an electrostatic chuck in which a chuck electrode is embedded in a dielectric member, such as ceramic, to attract the substrate W.

The substrate mounting part 11 has a mounting surface 11S and a back surface 11T located on the opposite side of the mounting surface 11S. The substrate mounting part 11 places the substrate on the mounting surface 11S. The temperature measuring part 12 is attached to the back surface 11T of the substrate mounting part 11. The substrate mounting part 11 has a recess 11h that opens toward the back surface 11T. The tip end of the temperature measuring part 12 is inserted into the recess 11h.

The temperature measuring part 12 measures the temperature of the substrate mounting part 11. The temperature measuring part 12 includes, e.g., a thermocouple. The temperature measuring part 12 further includes, e.g., a protective line 12t having therein a thermocouple to protect the thermocouple. The temperature measuring part 12 has a rod shape.

The temperature measuring part 12 has a temperature detection point 12s at the tip end of the protective line 12t. Specifically, two types of metal lines of the thermocouple are joined to the temperature detection point 12s. The temperature measured at the temperature detection point 12s in the temperature measuring part 12 is inputted to the controller 2 through a wiring 12i.

The heat transfer promoting part 13 promotes heat transfer from the substrate mounting part 11 to the temperature measuring part 12 when the temperature at the substrate mounting part 11 is measured by the temperature measuring part 12.

The heat transfer promoting part 13 includes a heat transfer sheet 13a, a heat transfer part 13b, and a clamp 13c.

The heat transfer part 13b transfers heat from the substrate mounting part 11 to the temperature measuring part 12. The heat transfer part 13b has a flange portion 13b1 and a cylindrical portion 13b2. The heat transfer part 13b has a through-hole 13bh at the center thereof, through which the temperature measuring part 12 penetrates. An inner surface 13bA forming the through-hole 13bh is in contact with the temperature measuring part 12. The contact between the inner surface 13bA and the temperature measuring part 12 allows sufficient heat transfer from the heat transfer part 13b to the temperature measuring part 12.

The heat transfer part 13b has high thermal conductivity, and is made of a material with a small heat capacity. The heat transfer part 13b is made of silicon carbide, for example. The flange portion 13b1 and the cylindrical portion 13b2 are formed integrally. Since the heat transfer part 13b is made of a material with high thermal conductivity, the heat transfer part 13b can transfer heat transferred from the substrate mounting part 11 to the temperature measuring part 12 with a high response speed.

The flange portion 13b1 has a plate shape with holes. An upper surface 13bS of the flange portion 13b1 faces the back surface 11T of the substrate mounting part 11. The heat transfer sheet 13a is provided between the upper surface 13bS of the flange portion 13b1 and the back surface 11T of the substrate mounting part 11. The flange portion 13b1 is in thermal contact with the back surface 11T of the substrate mounting part 11.

Further, "A in thermal contact with an object" includes, e.g., a case where A is in contact with the object to directly transfer heat to the object, and a case where A is in contact with an object via a heat transfer member interposed between A and the object. Therefore, the case where the flange portion 13b1 is in thermal contact with the back surface 11T of the substrate mounting part 11 includes both a case where the flange portion 13b1 is in direct contact with the back surface 11T and a case where the flange portion 13b1 is in contact with the back surface 11T via the heat transfer sheet 13a.

The cylindrical portion 13b2 has a cylindrical shape. The cylindrical portion 13b2 protrudes downward from the flange portion 13b1.

The heat transfer sheet 13a transfers heat from the back surface 11T of the substrate mounting part 11 to the heat transfer part 13b. The heat transfer sheet 13a is provided between the back surface 11T of the substrate mounting part 11 and the heat transfer part 13b. The heat transfer sheet 13a is in contact with the back surface 11T of the substrate mounting part 11. The heat transfer sheet 13a is also in contact with the upper surface 13bS of the heat transfer part 13b. The heat transfer sheet 13a is brought into contact with the back surface 11T and the upper surface 13bS, so that the heat can be sufficiently transferred from the substrate mounting part 11 to the heat transfer part 13b. The heat transfer sheet 13a is made of, e.g., carbon, copper, silicon, or an alloy thereof.

The heat transfer sheet 13a is preferably made of a flexible material. Since the heat transfer sheet 13a is made of a flexible material, heat transfer can be achieved while suppressing heat transfer loss in minute gaps between surfaces.

The support part 14 supports the temperature measuring part 12 while pressing it against the back surface 11T of the substrate mounting part 11. The support part 14 is located at the bottom portion 20B of the processing chamber 20. The support part 14 has an elastic member for pressing the temperature measuring part 12 against the substrate mounting part 11. The elastic member is, e.g., a helical spring, a leaf spring, or another spring.

The clamp 13c presses the cylindrical portion 13b2 of the heat transfer part 13b from the outside. The clamp 13c presses the cylindrical portion 13b2 of the heat transfer part 13b from the outside, thereby fixing the heat transfer part 13b to the temperature measuring part 12.

The clamp 13c has a first portion 13c1 provided to face a bottom surface 13bT of the flange portion 13b1, and a second portion 13c2 provided to face a side surface 13bU of the cylindrical portion 13b2.

When the temperature measuring part 12 is pressed by the support part 14, the first portion 13c1 presses the bottom surface 13bT of the heat transfer part 13b toward the back surface 11T of the substrate mounting part 11. The first portion 13c1 presses the bottom surface 13bT of the heat transfer part 13b toward the back surface 11T of the substrate mounting part 11, thereby pressing the heat transfer sheet 13a toward the back surface 11T of the substrate mounting part 11. By pressing the heat transfer sheet 13a toward the back surface 11T of the substrate mounting part 11, the heat transfer from the back surface 11T of the substrate mounting part 11 to the flange portion 13b1 can be further promoted.

The second portion 13c2 presses the cylindrical portion 13b2 against the temperature measuring part 12. Since the second portion 13c2 presses the cylindrical portion 13b2 against the temperature measuring part 12, the heat transfer from the cylindrical portion 13b2 to the temperature measuring part 12 can be further promoted.

The clamp 13c is made of a material with a low heat capacity. For example, the clamp 13c is made of titanium or a titanium alloy. Further, the clamp 13c is formed thin to reduce the heat capacity of the clamp 13c.

The controller 2 processes computer-executable instructions that execute various processes in the substrate processing part 1. The controller 2 controls the processing performed in the substrate processing part 1. The controller 2 controls the temperature measuring part 12 to measure the temperature at the substrate mounting part 11. For example, the controller 2 uses the temperature at the substrate mounting part 11 measured by the temperature measuring part 12 to control the substrate W to a desired temperature.

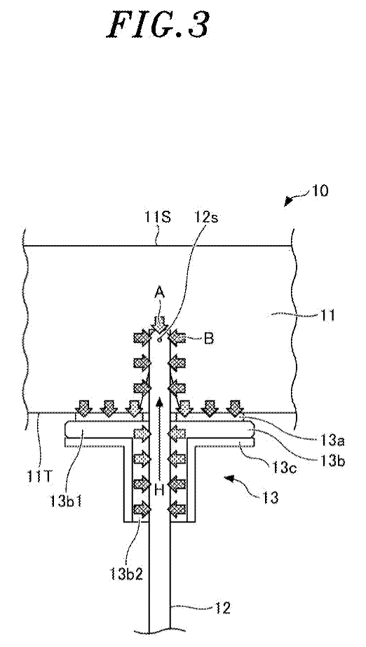

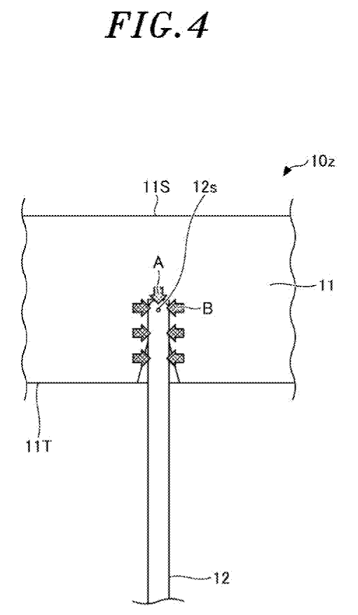

The heat flow to the temperature measuring part at the substrate support according to the embodiment will be described. FIG. 3 illustrates the heat flow near the attachment portion of the temperature measuring part 12 at the substrate support 10, which is an example of the substrate support according to the embodiment. FIG. 3 illustrates the processing chamber 20 in a vacuum state. As a reference example, a substrate support 10z without a heat transfer accelerator 13 is illustrated. FIG. 4 illustrates the heat flow near the attachment portion of the temperature measuring part 12 at the substrate support 10z of the reference example.

When heat is transferred between two components, heat transfer by contact (contact heat transfer), heat transfer through a medium therebetween (convective heat transfer), and heat transfer by radiation (radiant heat transfer) can be considered. In the case of considering heat transfer between the temperature measuring part 12 and the substrate mounting part 11, if the processing space 20s in the processing chamber 20 is in a vacuum state, the space between the temperature measuring part 12 and the substrate mounting part 11 becomes in a vacuum state. Thus, it is considered that there is almost no convective heat transfer between the temperature measuring part 12 and the substrate mounting part 11. Therefore, if the processing space 20s in the processing chamber 20 is in a vacuum state, the contact heat transfer and the radiant heat transfer are considered as the heat transfer between the temperature measuring part 12 and the substrate mounting part 11. The amount of heat transfer per unit area is smaller in the case of the radiant heat transfer compared to the case of the contact heat transfer.

In FIGS. 3 and 4, arrows A with a dotted pattern indicate contact heat transfer. Arrows B with a grid pattern indicate radiation heat transfer.

As shown in FIG. 4, it is considered that the contact heat is transferred from the substrate mounting part 11 to the temperature measuring part 12 only at the tip end portion. Further, the heat is transferred from the substrate mounting part 11 to the temperature measuring part 12 by radiant heat transfer. Therefore, in the substrate support 10z, the heat from the substrate mounting part 11 cannot be sufficiently transferred to the temperature detection point 12s of the temperature measuring part 12.

As shown in FIG. 3, more heat can be transferred to the temperature measuring part 12 by using the heat transfer promoting part 13 compared to the case of using the substrate support 10z. Specifically, the heat in the substrate mounting part 11 is transferred from the back surface 11T of the substrate mounting part 11 to the flange portion 13b1 of the heat transfer part 13b through the heat transfer sheet 13a by contact heat transfer and radiant heat transfer. Further, the heat in the substrate mounting part 11 is transferred from the flange portion 13b1 to the cylindrical portion 13b2. The heat transferred to the cylindrical portion 13b2 is transferred to the temperature measuring part 12 by contact heat transfer and radiant heat transfer. As indicated by a line H with an arrow, heat from the substrate mounting part 11 can be transferred from the position below the temperature detection point 12s.

As described above, the substrate support 10 includes the heat transfer promoting part 13, and thus can transfer more heat from the substrate mounting part 11 to the temperature detection point 12s in the temperature measuring part 12. By transferring more heat from the substrate mounting part 11 to the temperature detection point 12s in the temperature measuring part 12, the substrate support 10 can suppress offset in the measurement value and achieve a faster response time in performing temperature measurement.

For example, in measuring a temperature of a main body in an electrostatic chuck or a stage with a built-in heater, a thermocouple may be located on the atmospheric side to perform temperature measurement and control. A thermocouple body for performing temperature measurement generally has a spherical tip end. Since the tip end of the thermocouple body has a spherical shape, the thermocouple is in point contact with an object to be measured.

In a normal atmospheric environment, even if the thermocouple is in point contact with the object to be measured, heat transfer (convective heat transfer) to the atmosphere near the contact portion occurs because air exists around the contact portion, and the measurement result that is substantially the same as the actual temperature of the object to be measured can be obtained.

On the other hand, as described above, when a contact-type structure in which a thermocouple is brought into contact with an object to be measured is applied to a vacuum environment, heat propagation occurs only at the contact surface (point) between the surface to be measured and the thermocouple. Hence, heat transfer loss occurs, which results in a decrease in temperature responsiveness or a temperature offset.

If the temperature responsiveness is slow, the controllability decreases in the case of performing control using a measured temperature, which may lead to overshoot, undershoot, and fluctuation. Further, since the thermocouple is attached on the atmospheric side, it is required to attach and detach the thermocouple when a stage or the like is replaced. Thus, it is also required to attach and detach a thermocouple connector, which deteriorates workability.

Accordingly, in the substrate support of the present embodiment, the heat transfer from the substrate mounting part to the temperature measuring part is promoted by attaching the heat transfer part to the temperature measuring part. Specifically, in order to increase the contact area, a temperature measuring part such as a thermocouple is clamped with, for example, a silicon carbide component having high thermal conductivity and low heat capacity, and the clamped component itself is brought into contact with a stage or the like. Further, instead of bringing the surfaces of the heat transfer part and the substrate mounting part into direct contact with each other, a heat transfer sheet having flexibility that allows it to easily conform to surface properties and having high thermal conductivity, such as a carbon sheet, is interposed between the contact surfaces.

Due to the above-described operation, in the substrate support of the present embodiment, the temperature measurement using a contact-type thermocouple in a vacuum environment can be performed in the same manner as that in an atmospheric environment. Further, in the substrate support of the present embodiment, the contact area is increased by the surface contact of the body of the heat transfer part, thereby suppressing heat transfer loss and improving temperature responsiveness. Moreover, in the substrate support of the present embodiment, by interposing a heat transfer sheet having high flexibility and high thermal conductivity between the heat transfer part and the substrate mounting part, heat conduction can be achieved while suppressing heat transfer loss in minute gaps between the surfaces. Further, since the substrate support of the present embodiment can be provided with a structure for heat conduction in a vacuum environment, it is possible to replace only the stage, thereby improving replacement workability.

The substrate processing apparatus according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

1. A substrate support comprising:
a substrate mounting part having a mounting surface for mounting a substrate, a back surface provided on the opposite side of the mounting surface, and a recess formed in the back surface;
a rod-shaped temperature measuring part configured to detect a temperature at a tip end thereof, the tip end being inserted into and brought into contact with the recess to detect a temperature; and
a heat transfer part including a plate-shaped flange portion having a through-hole through which the temperature measuring part penetrates and in thermal contact with the back surface, and a cylindrical portion protruding from the flange portion and whose inner surface is brought into contact with the temperature measuring part.

2. The substrate support of claim 1, wherein the heat transfer part is made of silicon carbide.

3. The substrate support of claim 1, further comprising:
a heat transfer sheet provided between the flange portion and the back surface.

4. The substrate support of claim 2, further comprising:
a heat transfer sheet provided between the flange portion and the back surface.

5. The substrate support of claim 3, wherein the heat transfer sheet is made of carbon, copper, silicon, or an alloy thereof.

6. The substrate support of claim 1, wherein the temperature measuring part is pressed against and brought into contact with the recess by an elastic member.

7. The substrate support of claim 2, wherein the temperature measuring part is pressed against and brought into contact with the recess by an elastic member.

8. The substrate support of claim 1, further comprising:
a clamp that presses the cylindrical portion against the temperature measuring part.

9. The substrate support of claim 2, further comprising:
a clamp that presses the cylindrical portion against the temperature measuring part.

10. The substrate support of claim 8, wherein the clamp is made of a material with a small heat capacity compared to the cylindrical portion.

11. The substrate support of claim 10, wherein the material is titanium.

12. The substrate support of claim 1, further comprising:
an electrostatic chuck or a temperature controller configured to control a temperature of the substrate.

13. The substrate support of claim 2, further comprising:
an electrostatic chuck or a temperature controller configured to control a temperature of the substrate.

14. A substrate processing apparatus comprising:
a processing chamber; and
the substrate support of claim 1, provided in the processing chamber.
